(19) United States
(12) Patent Application Publication
(10) Pub. No.: US 2011/0083889 A1
(43) Pub. Date: Apr. 14, 2011

(54) FPC-Based Relay Connector

(75) Inventors: Toshihiro Niitsu, Tokyo (JP); Yuichi Hasegawa, Yokohama (JP)

(73) Assignee: Molex Incorporated, Lisle, IL (US)

(21) Appl. No.: 12/666,065

(22) PCT Filed: Jun. 25, 2008
(86) PCT No.: PCT/US08/07910

§ 371 Date: Nov. 15, 2010

(30) Foreign Application Priority Data
Jun. 25, 2007 (JP) 2007-165815

(51) Int. Cl. H05K 1/00

(52) U.S. Cl. 174/258; 174/250

(57) ABSTRACT

A bridge connector for interconnecting two connectors mounted on circuit boards together includes a planar substrate that supports a length of flexible printed circuit, the substrate has engagement arms that are chamfered to act as male connector portions and be received within receptacle portions for the board connectors to effect a reliable connection between the two connectors.

### BACKGROUND OF THE INVENTION

1. Field of the Invention

The present invention relates to a relay connector.

2. Description of the Related Art

Hitherto, a board-to-board connector has been used in order to connect a pair of parallel circuit boards to each other (refer to, for example, Japanese Patent Application Laid-Open (Kokai) publication No. 2003-272734). This type of board-to-board connector connects a pair of circuit boards arranged in parallel on an identical surface to one another.

FIG. 15 is a side view of a conventional board-to-board connector.

In the same drawing, reference numeral 901 designates a first connector to be mounted on a first circuit board 991A, reference numeral 902 designates a second connector to be fitted to a counterpart connector mounted on a second circuit board 991B, and reference numeral 801 designates a linking connector for providing electrical connection between the first connector 901 and the second connector 902. The first connector 901 is provided with a housing 911 and solder tails 961 projecting from the housing 911, and the solder tails 961 are connected to corresponding conductive traces of the first circuit board 911A. Therefore, the first connector 901 is mounted on the first circuit board 991A.

Further, the second connector 902 is provided with a housing 912, and contact portions 962 attached to the housing 912, and connected by fitting to the counterpart connector mounted on the second circuit board 991B. Accordingly, the contact portions 962 come into contact and become electrically continuous with counterpart terminals of the counterpart connector.

The linking connector 801 is provided with a housing 811, and pivotally connected to the first connector 901. In this case, pivotal shaft pins 915 formed on both sides of the housing 911 of the first connector 901 are pivotally fitted into receiving grooves 813 formed in the housing 811 of the linking connector 801. The housing 912 of the second connector 902 is fixed to the housing 811 of the linking connector 801.

Further, the linking connector 801 includes a plurality of jumper leads 861 arranged in parallel with each other. The jumper leads 861 are formed of flexible conductive metal leads, and both ends of each are connected to each of the solder tails 961 and each of the contact portions 962. In other words, the solder tails 961 of the first connector 901 and the contact portions 962 of the second connector 902 are connected to each other by the jumper leads 861.

A conventional board-to-board connector has the structure described above, and in states of storage, transportation and so forth, the first connector 901 is mounted on the first circuit board 991A, and the second connector 902 and the counterpart connector are unlocked from each other. Therefore, even if the relative locations of the first circuit board 991A and the second circuit board 991B are shifted due to an externally applied shock or the like, no stress is applied thereto from the shock or the like. Moreover, when connecting the first circuit board 991A and the second circuit board 991B to one another, the linking connector 801 is pivoted with respect to the first connector 901 mounted on the first circuit board 991A, while allowing the second connector 902 to be fitted to the counterpart connector mounted on the second circuit board 991B. Hence, the contact portions 962 come into contact with the counterpart terminals of the counterpart connector, and thereby the first circuit board 991A and the second circuit board 991B are connected to each other, in other words, to the electric circuits provided on each of the circuit boards.

Further, even if the locations are shifted between the first circuit board 991A and the second circuit board 991B in a state of being connected to each other by the board-to-board connector, the location shift can be adequately absorbed because the fitting state between the pivotal shaft pins 915 and the receiving grooves 813 is kept loose, and the jumper leads 861 are flexible and can be permitted to be easily bended.

However, in the described conventional board-to-board connector, the linking connector 801 includes the plurality of jumper leads 861, and the plurality of jumper leads 861 are integrated with the housing 811 made of synthetic resin or the like. Therefore, in order to produce the connecting connector 801, it is necessary to use a metallic-terminal die which has a function of holding the jumper leads 861 that are the metallic terminals, to form the housing 811, by filling the metallic-terminal die with molten resin. However, costs for such metallic-terminal die are high because the structure thereof is generally complex, causing an increase in the manufacturing costs for the linking connector 801.

Moreover, since the jumper leads 861 bend when a location shift occurs between the first circuit board 991A and the second circuit board 991B, if, in particular, the pitch of the jumper leads 861 is small, the neighboring jumper leads 861 must contact with each other when they bend, which increase the possibility of occurrence of the so-called short-circuit between different leads. Hence, another component to avoid short-circuit between the leads is necessary to prevent the neighboring jumper leads 861 from being in contact with each other, and this causes an increase in the number of components, and the structure and arrangement become more complicated.

Nevertheless, since FPC (flexible printed circuit) and FFC (flexible flat cable) inherently have flexibility, the FPC and FFC for high-speed transmission might be employable, instead of the conventional board-to-board connector, to connect the first circuit board 991A and the second circuit board 991B to one another. However, in this case, both ends of the flexible FPC or FFC have to be connected to connectors mounted on the first circuit board 991A and the second circuit board 991B one by one, and therefore it takes lots of effort and time to achieve the operation.

### SUMMARY OF THE INVENTION

Therefore, it is an object of the invention to solve the problems encountered by the conventional connector described above, and to provide a relay connector in which a three-dimensional conductive patterns are formed on surfaces of a body portion which is integrally formed of an insulating material, whereby an operation for fitting the connector to a mounted counterpart connector or connectors can be easily performed, any short-circuit between the conductive patterns do not occur, desired conductive patterns can be readily formed, a structure and an amendment is simple, the number of required components is small, and easy production as well as low production cost can be ensured.

Therefore, a relay connector according to the present invention comprises a body portion provided with a plurality of fitting portions to be fitted to counterpart connectors, respectively, and integrally formed of an insulating material, and conductive patterns in three dimensions, which are formed on surfaces of the body portion, the conductive patterns being capable of coming into contact with counterpart terminals of the counterpart connectors, thereby connecting the plurality of counterpart connectors to one another.

In the relay connector according to another embodiment of the present invention, the body portion is provided with a plate-like bridging portion, and the fitting portions are connected to the bridging portion at both ends of the bridging portion spaced apart in a direction in which the conductive patterns extend, the fitting portions extending, respectively, in a direction perpendicular to the bridging portion.

In the relay connector according to a further embodiment of the present invention, the conductive patterns comprise first conductive patterns which include a first portion formed on a surface of the bridging portion, and second portions formed on surfaces of the fitting portions and connected to the first portion, and second conductive patterns which include a first portion formed on a rear surface of the bridging portion, and second portions formed on rear surfaces of the fitting portions and connected to the first portion.

In the relay connector according to a still further embodiment of the present invention, the body portion further comprises chamfered portions formed in border portions between the surface of the bridging portion and the surfaces of the fitting portions, and chamfered portions formed in border portions between the rear surface of the bridging portion and the rear surfaces of the fitting portions.

In the relay connector according to a still further embodiment of the present invention, the surfaces of the fitting portions include recessed surface portions on which the second portions of the first conductive patterns are formed, and projecting portions projecting further than the recessed surface portions, and the rear surfaces of the fitting portions include recessed surface portions on which the second portions of the second conductive patterns are formed, and projecting portions projecting further than the recessed surface portions.

In the relay connector according to a still further embodiment of the present invention, at least one of the fitting portions is divided into a plurality of portions with respect to a direction of array of the conductive patterns, and the plurality of portions are arranged to be offset from one another with respect to a longitudinal direction of the conductive patterns.

In the relay connector according to a still further embodiment of the present invention, the insulating material comprises a composite material obtained by mixing an organic metal with a base polymer, and the conductive patterns are formed of a metal plating film deposited on patterns formed by irradiating a beam of laser onto the surfaces of the body portion.

In accordance with the present invention, the relay connector is formed with the conductive patterns in three dimensions on the surfaces of the body portion, which is integrally formed of an insulating material. Hence, an operation for fitting the relay connector to the counterpart connectors mounted on a substrate or a circuit board is performed easily, no short-circuit between the conductive patterns occurs, desired types of conductive patterns can be readily formed, the structure and arrangement can be simplified, the number of components required is reduced, production of the relay connector is made easier while achieving reduction in the production cost thereof.

### BRIEF DESCRIPTION OF THE DRAWINGS

FIG. 1 is a perspective view illustrating a state where a relay connector according to a first embodiment of the present invention is fitted to counterpart connectors, and a cover member is attached thereto;

FIG. 2 is a cross-sectional view, taken along the arrowed line A-A of FIG. 1, depicting the state where the relay connector according to the first embodiment of the present invention is fitted to the counterpart connectors;

FIG. 3 is a perspective view illustrating the state where the relay connector according to the first embodiment of the present invention is fitted to the counterpart connectors;

FIG. 4 is an exploded perspective view illustrating a relationship among the relay connector according to the first embodiment of the present invention, the counterpart connectors, and the cover member;

FIG. 5 is a perspective view of the relay connector according to the first embodiment of the present invention;

FIGS. 6A and 6B are first views from the two different sides of the relay connector according to the first embodiment of the present invention, in which FIG. 6A is a top plan view thereof and FIG. 6B is a front view thereof;

FIGS. 7A and 7B are second views from the two different sides of the relay connector according to the first embodiment of the present invention, in which FIG. 7A is one side view thereof and FIG. 7B is a bottom view thereof;

FIGS. 8A and 8B are different cross-sectional views of the relay connector according to the first embodiment of the present invention, one (FIG. 8B) being a view taken along the arrowed line B-B of FIG. 6B, and the other (FIG. 8A) being an enlarged view of portion “C” of FIG. 8B;

FIGS. 9A and 9B are views illustrating a state where a body portion of the relay connector according to the first embodiment of the present invention is irradiated with a beam of laser;

FIG. 10 is a first perspective view of a relay connector according to a second embodiment of the present invention;

FIG. 11 is a second perspective view of the relay connector according to the second embodiment of the present invention;

FIGS. 12A to 12C are three-sided views of the relay connector according to the second embodiment of the present invention, in which FIG. 12A is a top plan view thereof, FIG. 12B is a front view thereof, and FIG. 12C is a side view thereof;

FIG. 13 is a bottom view of the relay connector according to the second embodiment of the present invention;

FIG. 14 is a perspective view illustrating a state where the relay connector according to the second embodiment of the present invention is fitted to counterpart connectors; and

FIG. 15 is a side view of a conventional board-to-board connector.

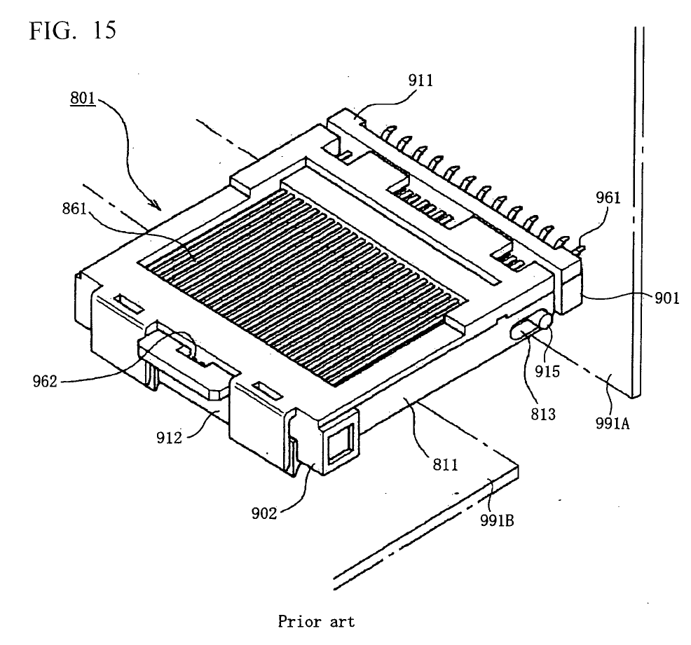

### DESCRIPTION OF THE PREFERRED EMBODIMENT

Preferred embodiments of the present invention will be described hereinbelow in detail with reference to the accompanying drawings.

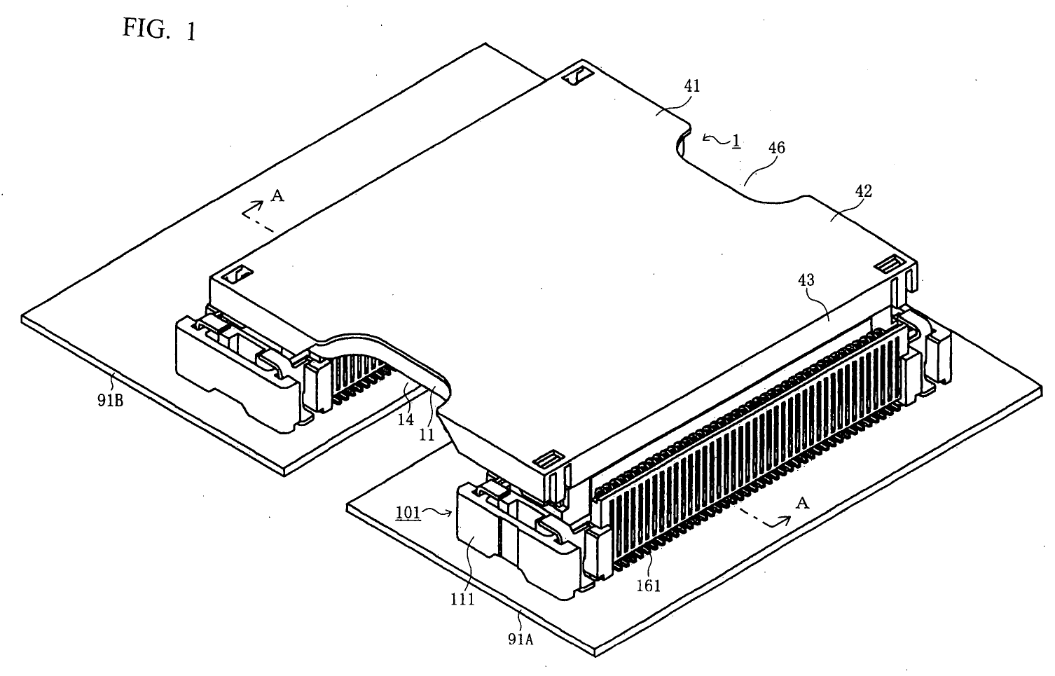

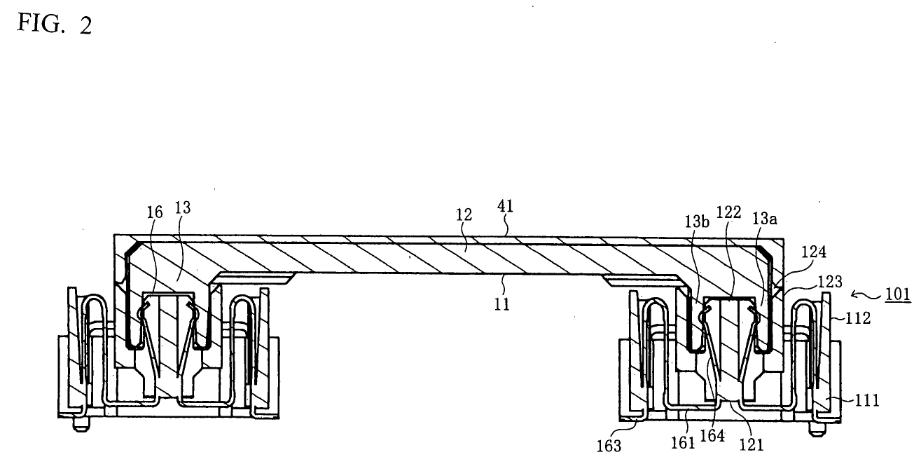

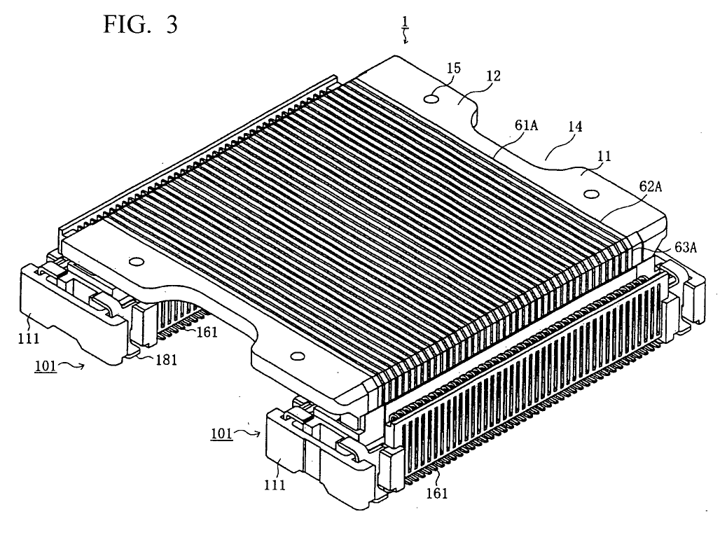

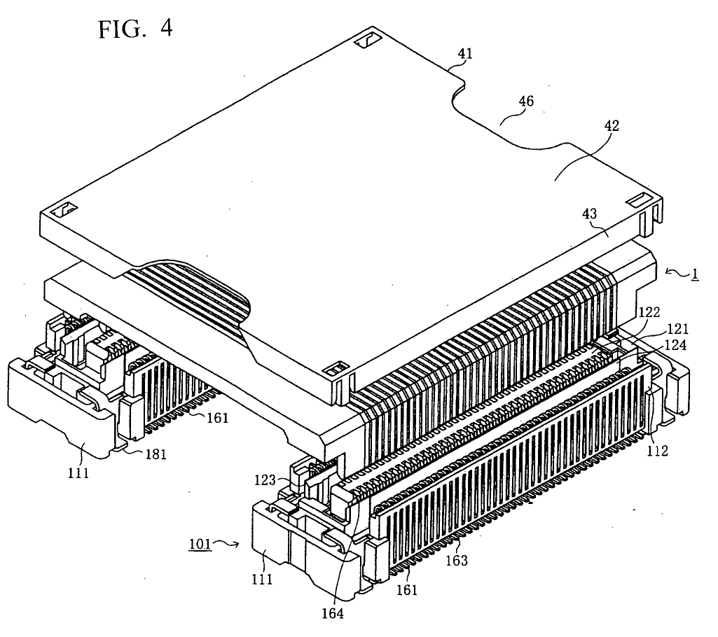

FIG. 1 is a perspective view illustrating a state where a relay connector according to a first embodiment of the present invention is fitted to counterpart connectors, and a cover member is attached thereto, FIG. 2 is a cross-sectional view, taken along the arrowed line A-A of FIG. 1, depicting the state where the relay connector according to the first embodiment of the present invention is fitted to the counterpart connectors, FIG. 3 is a perspective view illustrating the state where the relay connector according to the first embodiment of the present invention is fitted to the counterpart connectors, and FIG. 4 is an exploded perspective view illustrating a relationship among the relay connector according to the first embodiment of the present invention, the counterpart connectors, and the cover member.

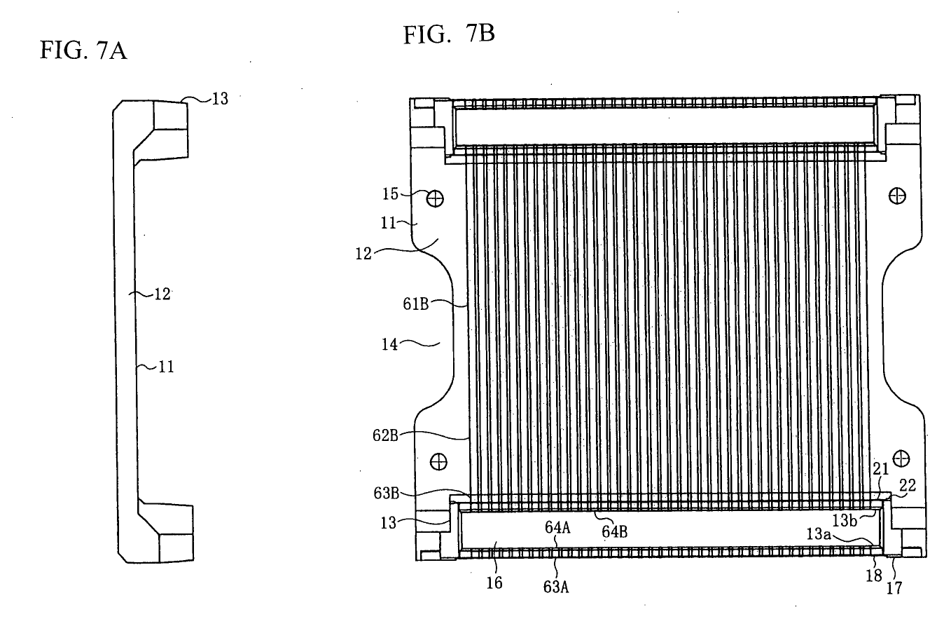

In the drawing figures, reference numeral 1 generally denotes a connector as a relay connector according to the present first embodiment, and the relay connector 1 includes a body portion 11 formed of an insulating material such as synthetic resin, and conductive patterns 61 formed on surfaces of the body portion 11, and can electrically connect a first substrate 91A and a second substrate 91B when both ends thereof are fitted to counterpart connectors 101 mounted on the first substrate 91A and the second substrate 91B, respectively. The conductive patterns 61 includes first conductive patterns 61A formed on a first surface of the body portion 11, namely, the uppermost surface of the body portion 11, and later described second conductive patterns 61B formed on a second surface of the body portion 11, namely, the rear surface of the body portion 11 (refer to FIG. 7B), and, it is to be noted that when the first conductive patterns 61A and the second conductive patterns 61B are described collectively, both will be described as the conductive patterns 61. The first substrate 91A and the second substrate 91B are, for example, printed circuit boards, but they may be any type of substrates as long as electric circuits are provided.

In the present embodiment, representations of directions such as up, down, left, right, front, rear, and the like, used for explaining the structure and movement of each part of the connector 1, and the like, are not absolute, but relative. These representations are appropriate when each part of the connector 1, and the like, is in the position shown in the figures. If the position of the connector 1, and the like, changes, however, it is assumed that these representations are to be changed according to the change in the position of the connector 1, and the like.

The body portion 11 is a member which is integrally formed of an insulating material such as synthetic resin, to be more specific, a composite material of thermoplastic resin containing organic metal, and includes a plate-like rectangular bridging portion 12, and leg portions 13 as fitting portions extending in a direction perpendicular to the bridging portion 12 (the downward direction in FIG. 2) in which the distal ends thereof are connected to both ends of the bridging portion 12. As shown in FIG. 2, each of the leg portions 13 is provided with a fitting-recess portion 16 to be fitted to a center wall portion 122 of each of counterpart connectors 101. Each of the fitting-recess portions 16 is a recess which is open on the bottom surface of each of the leg portions 13, the cross section thereof extending in the array direction of the conductive patterns 61 (a direction connecting the right top and left bottom in FIG. 1) is rectangle or trapezoidal, and both sides thereof are defined by an external wall portion 13a and an internal wall portion 13b of each of the leg portions 13.

As shown in FIG. 3, the plurality of first conductive patterns 61A extending in a direction of connecting the leg portions 13 on both sides are formed so as to be parallel to each other on the surface of the body portion 11. On the rear surface of the body portion 11, a plurality of conductive patterns forming the later-described second conductive patterns 61B are extending in the direction of connecting the legs portions 13 on both sides, similarly to the first conductive patterns 61A, and formed so as to be parallel to each other.

The connector 1 according to the present embodiment is so-called a MID (Molded Interconnect Device), in which the conductive patterns 61, three-dimensional patterns, are integrally formed by plating on the surfaces of the body portion 11 which is formed of synthetic resin. In this case, the body portion 11 is formed of a composite material obtained by mixing a filler and organic metal with thermoplastic resin, which is base polymer, and is integrally molded into a desired shape by using a forming method such as an injection molding where a metallic die is used. Since the afore-mentioned organic metal is non-conductive, the composite material is an insulating material. Thereafter, the surfaces of the body portion 11 are radiated with a beam of laser for the patterning, and predetermined patterns, which correspond to the conductive patterns 61 are formed. Then, laser-radiated areas on the surfaces of the body portion 11 are activated, a physicochemical reaction of the organic metal is induced in these areas, and metal seeds are generated. Moreover, these areas are roughened by so-called laser abrasion. Since these areas have metal seeds and are roughened, deposition thereon of plating films can be high.

When highly conductive metal such as copper is applied, by plating, onto the surfaces of the body portion 11 patterned as described above, plating films are securely deposited on the laser-illuminated areas, and the conductive patterns 61 are formed there. Therefore, for example, approximately 80 linearly extending conductive patterns 61 arrayed with a fine pitch of about 100 [μm] can be obtained.

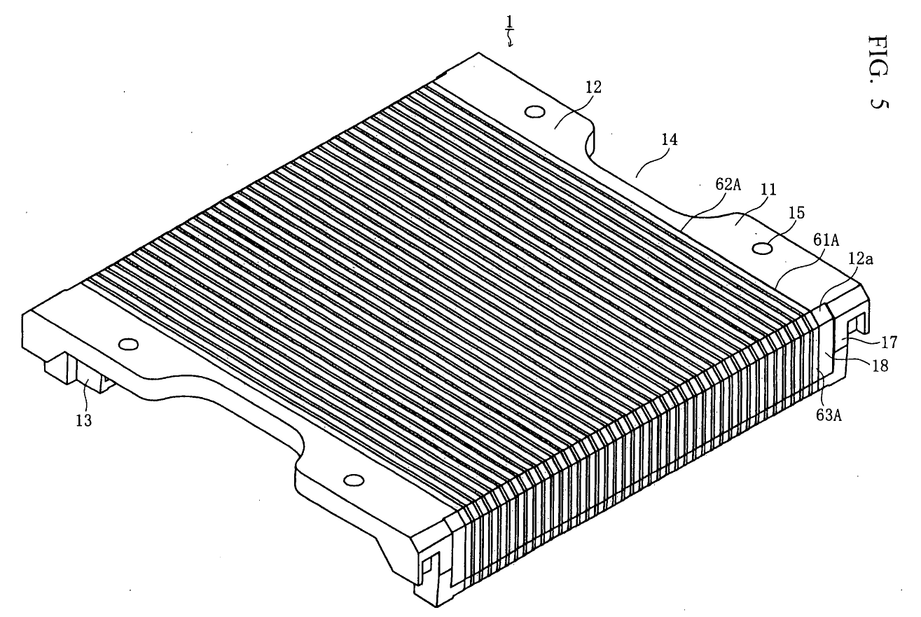

The conductive patterns 61 have a three-dimensional shape because they are formed along three-dimensional surfaces of the body portion 11. As shown in FIG. 5, the first conductive patterns 61A include a first portion 62A formed on the surface of the bridging portion 12, second portions 63A formed on the surfaces of the leg portions 13 on both sides, in other words, on the external surfaces of the external wall portions 13a, and one ends thereof are connected to both ends of the first portion 62A, and later-described third portions 64A formed on the side surfaces of the fitting-recess portions 16 on the external sides, namely, on the inner side surfaces of the external wall portions 13a, and one ends thereof are connected to the other ends of the second portions 63A (refer to FIG. 7B). Since the external side surface and the inner side surface of each of the external wall portions 13a are almost orthogonal to the surface of the bridging portion 12, the second portions 63A and the third portions 64A extend in a direction almost orthogonal to the first portion 62A.

Moreover, similarly to the first conductive patterns 61A, the second conductive patterns 61B include a first portion 62B formed on the rear surface of the bridging portion 12, second portions 63B formed on the rear surfaces of the leg portions 13 on both sides, namely, on the external side surfaces of the internal wall portions 13b, and one ends thereof are connected to both ends of the first portion 62B, and third portions 64B formed on the internal surfaces of the internal wall portions 13b, and one ends thereof are connected to the other ends of the second portions 63B (refer to FIG. 7B).

Once the leg portions 13 on both sides are fitted to the counterpart connectors 101 mounted on the first substrate 91A and the second substrate 91B, respectively, the first portion 63A of the third conductive patterns 64A of the first conductive patterns 61A and the third portions 64B of the second conductive patterns 61B come into contact with counterpart terminals 161 of the counterpart connectors 101. Therefore, the counterpart terminals 161 of the counterpart connectors 101 mounted on the first substrate 91A and the second substrate 91B, respectively, are electrically connected to one another via the first conductive patterns 61A and the second conductive patterns 61B.

Here, the counterpart connector 101 is a so-called floating type connector, and includes an external housing 111 and an internal housing 121 integrally formed of an insulating material such as synthetic resin, and the plurality of counterpart terminals 161 formed of conductive metal and attached to the external housing 111 and the internal housing 121. The internal housing 121 is accommodated in the external housing 111. Because the external housing 111 and the internal housing 121 are independently formed members that are separate from each other, and connected to each other by the counterpart terminals 161, the internal housing 121 is loosely restrained by the external housing 111 so as to be able to be displaced with respect to the external housing 111 as the counterpart terminals 161 are elastically deformed, that is to say, the internal housing 121 is in a floating state.

The external housing 111 is a member which has a square tubular shape with a rectangular plane cross section, and includes side wall portions 112 which are in parallel with each other and extend in the longitudinal direction. The internal housing 121 is a member having a square columnar shape with a rectangular plane cross section, and includes the center wall portion 122, two fitting wall portions 123 extending in the longitudinal direction, and two fitting groove portions 124 formed between the center wall portion 122 and the fitting wall portions 123 and extending in the longitudinal direction.

The counterpart terminals 161 are arrayed with a predetermined pitch, forming two rows extending in the longitudinal direction of the counterpart connector 101, mounted on the external housing 111 and the internal housing 121 so as to straddle over both housings, and exhibit a function of physically coupling the external housing 111 and the internal housing 121.

The external housings 111 are mounted and fixed onto the first substrate 91A and the second substrate 91B, respectively. In this case, the external housings 111 are fixed thereto, as tail portions 163 connected to one ends of the counterpart terminals 161 are connected to connecting pads which are coupled to non-illustrated conductive traces of the first substrate 91A and the second substrate 91B by soldering or the like, and additionally, auxiliary metallic bracket members 181 usually referred to as nail members are attached to the connecting pads or the like on the first substrate 91A and the second substrate 91B by soldering or the like so as to ensure the fixing of the external housings 111.

Moreover, contact portions 164 connected to the other ends of the counterpart terminals 161 are in a state of projecting into the fitting groove portions 124 from both sides of the center wall portion 122. When the leg portions 13 on both sides of the connector 1 are fitted into the counterpart connectors 101, the center wall portions 122 enter the fitting-recess portions 16, and the external wall portions 13a and the internal wall portions 13b enter the fitting groove portions 124 arranged on both sides of the center wall portions 122, as shown in FIG. 2. Accordingly, the contact portions 164 come into contact with the third portions 64A and 64B formed on the inner side surfaces of the external wall portions 13a and the internal wall portions 13b, thus enabling the counterpart terminals 161 to be electrically conductive with the first conductive patterns 61A and the second conductive patterns 61B.

Preferably, a cover member 41 is attached to the body portion 11 of the connector 1 to cover the top surface thereof as shown in FIGS. 1, 2 and 4. In the example depicted in these drawing figures, the cover member 41 includes a flat plate-like top plate portion 42, which is approximately rectangle and covers the top surface of the body portion 11, and opposite skirt portions 43 extending in the downward direction from the side edge of the top plate portion 42. By covering the top surface of the body portion 11 with the cover member 41, any foreign matters such as fine dusts in the air do not attach to the surface of the body portion 11, preventing short-circuits from occurring between the neighboring first conductive patterns 61A. Therefore, engagement holes 15 are formed in an area of the bridging portion 12 of the body portion 11 where the conductive patterns 61 are not formed, enabling the non-illustrated engagement projections provided in the cover member 41 to be engaged in the engagement holes 15.

Furthermore, it is desirable that manipulating recessed portions 14 are provided on both ends of the bridging portion 12 in the direction of array of the conductive patterns 61. An operator can hold the body portion 11 easily and without failure by getting his/her fingers caught in the manipulating recessed portions 14 when carrying out diverse operations required for transporting the connector 1, fitting the connector 1 to the counterpart connectors 101, and the like. Moreover, it is desirable that manipulating recessed portions 46 having shapes corresponding to the manipulating recessed portions 14 are provided in the top plate portion 42 of the cover portion 41 at locations corresponding to the manipulating recessed portions 14.

Next, the structure of the connector 1 will be described in detail.

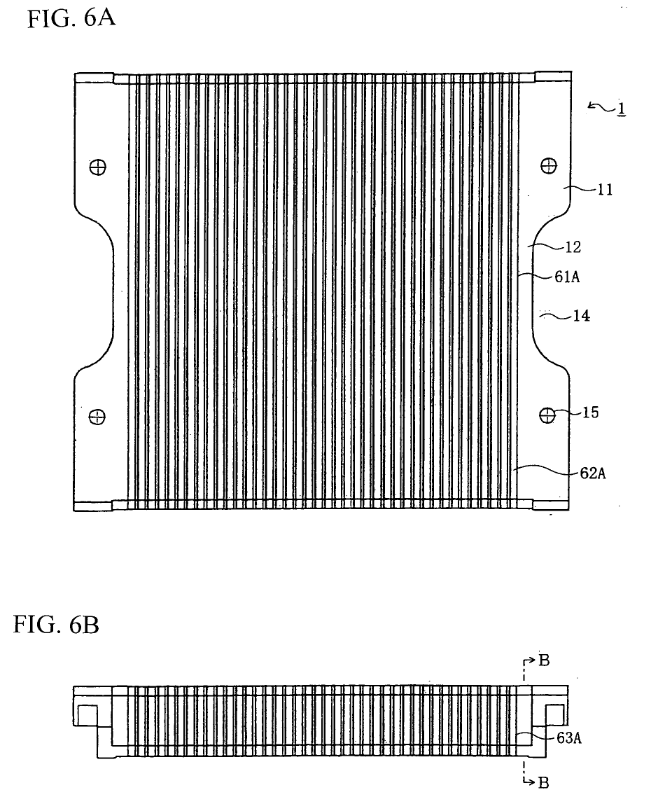

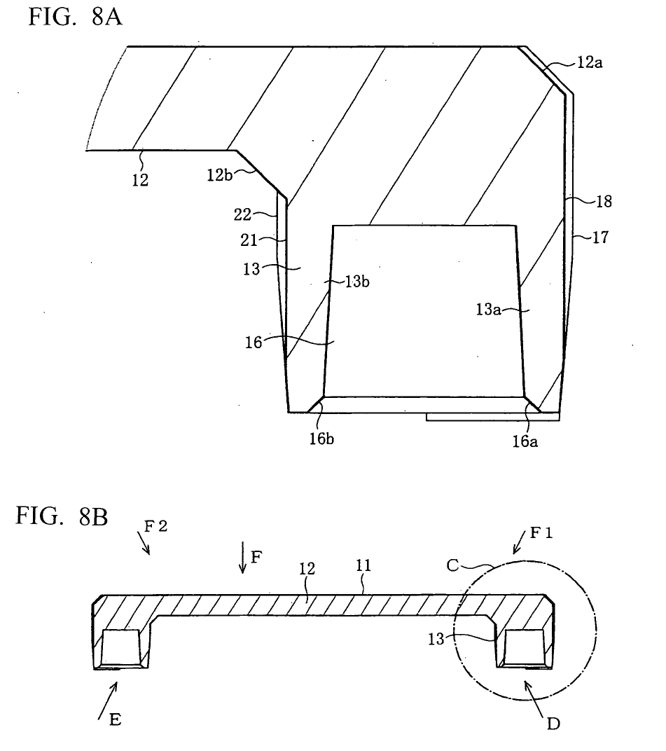

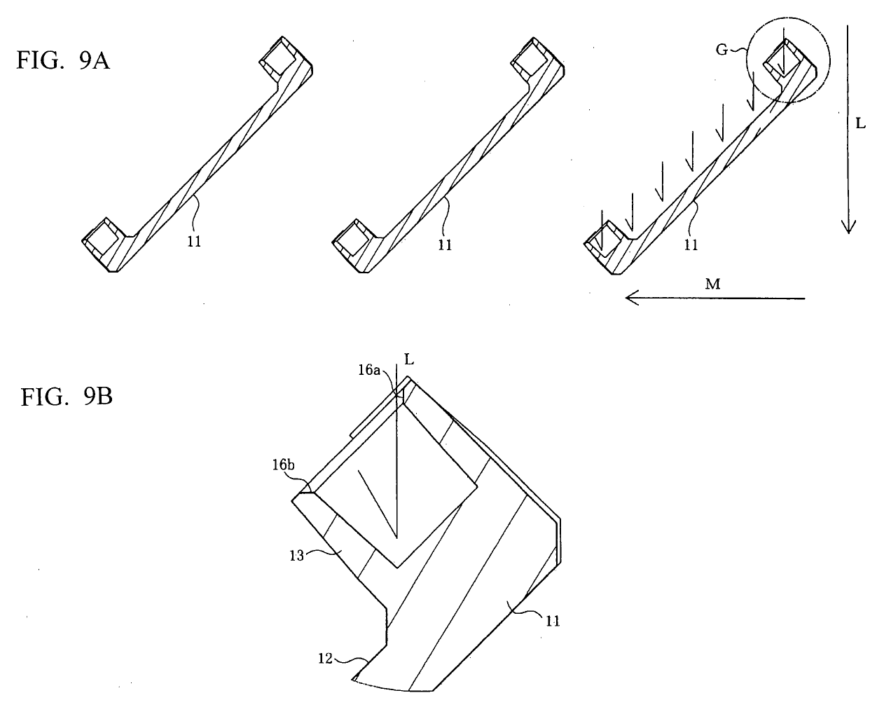

FIG. 5 is a perspective view of the relay connector according to the first embodiment of the present invention, FIGS. 6A and 6B are first views from the two different sides of the relay connector according to the first embodiment of the present invention, in which FIG. 6A is a top plan view thereof and FIG. 6B is a front view thereof, FIGS. 7A and 7B are second views from the two different sides of the relay connector according to the first embodiment of the present invention, in which FIG. 7A is one side view thereof and FIG. 7B is a bottom view thereof, FIGS. 8A and 8B are different cross-sectional views of the relay connector according to the first embodiment of the present invention, one (FIG. 8B) being a view taken along the arrowed line B-B of FIG. 6B, and the other (FIG. 8A) being an enlarged view of portion “C” of FIG. 8B, and FIGS. 9A and 9B are views illustrating a state where a body portion of the relay connector according to the first embodiment of the present invention is irradiated with a beam of laser.

As shown in FIGS. 5, 8A and 8B, chamfered portions 12a are formed in corner portions which form border portions between the surface of the bridging portion 12 and the external side surfaces of the external wall portions 13a. Therefore, in the first conductive patterns 61A, an connecting angle between the first portion 62A formed by plating on the surface of the bridging portion 12 and each of the second portions 63A formed by plating on the external side surface of each of the external wall portions 13a becomes gentler, ensuring connection between the first portion 62A and the second portions 63A. This means that, if the angle of the border portion between the surface of the bridging portion 12 and the external side surface of each of the external wall portions 13a is as sharp as approximately 90 degrees, a plating film on the surface of the bridging portion 12 and a plating films on the external side surfaces of the external wall portions 13a may not become continuous with each other when forming the plating films, whereas provision of gentler angles of the boarder portions ensures that the both plating films are successfully continuous with each other. Moreover, when conducting the patterning by the laser beam radiation, if the angles of the boarder portions between the surface of the bridging portion 12 and the external side surfaces of the external wall portions 13a are as sharp as approximately 90 degrees, the patterns on the surface of the bridging portion 12 and the patterns on the external side surfaces of the external wall portions 13a may not be smoothly connected adequately, whereas both patterns are continuous with each other properly due to the gentler angles of the border portions.

Furthermore, by forming the chamfered portions 12a, in addition to ensuring continuity between the first portion 62A and the second portions 63A in a step of production of the first conductive patterns 61A, the possibility of disconnection between both portions 62A and 63A is reduced even when any other object or the like abuts against the first portion 62A and the second portions 63A while mounting or using the connector 1. In the example illustrated in the drawings, the chamfered portions 12a are inclined flat surfaces, but the chamfered portions 12a may be curved surfaces that connect the surface of the bridging portion 12 and the external side surfaces of the external wall portions 13a.

Further, as shown in FIGS. 8A and 8B, chamfered portions 16a are also formed in corner portions which form border portions between the end portions of the fitting-recess portions 16 on the open side, in other words, the bottom surfaces of the leg portions 13, and the inner side surfaces of the external wall portions 13a. Since the chamfered portions 16a can exhibit functions similar to those exhibited by the chamfered portions 12a, forming the chamfered portions 16a ensure continuity between the second portions 63A formed by plating on the external side surfaces of the external wall portions 13a and the third portions 64A formed by plating on the internal side surfaces of the external wall portions 13a. Moreover, the possibility of disconnection between the second portions 63A and the third portions 64A is reduced. Furthermore, the chamfered portions 16a may be curved surfaces, in a manner similar to the chamfered portions 12a.

Although omitted in the example shown in the drawings, it is preferable that chamfered portions similar to the chamfered portions 16a are formed in corner portions which form border portions between the bottom surfaces of the leg portions 13 and the external side surfaces of the external wall portions 13a. Accordingly, continuity between the second portions 63A and the third portions 64A is ensured even further, and the possibility of disconnection between the second portions 63A and the third portions 64A is further reduced.

As shown in FIGS. 8A and 8B, the chamfered portions 12b similar to the chamfered portions 12a are formed in corner portions which form border portions between the rear surface of the bridging portion 12 and the external side surfaces of the internal wall portions 13b. Since the chamfered portions 12b can exhibit functions similar to those exhibited by the chamfered portions 12a, forming the chamfered portions 12b ensures continuity in the second conductive patterns 61B between the first portion 62B formed by plating on the rear surface of the bridging portion 12 and the second portions 63B formed by plating on the external side surfaces of the internal wall portions 13b.

When conducting the patterning by laser beam radiation in particular, if the angles of the border portions between the rear surface of the bridging portion 12 and the external side surfaces of the internal wall portions 13b are as sharp as nearly 90 degrees, it is difficult for the beam of laser to reach the border portions as they are narrow areas sandwiched by the inner surface of the bridging portion 12 and the external side surfaces of the inner wall portions 13b, and which increases the likelihood that the patterns on the inner surface of the bridging portion 12 and the patterns on the external side surfaces of the internal wall portions 13b are not smoothly continuous with each other properly, whereas the gentler angles of the border portions makes it easier for the beam of laser to be radiated so as to reach the boarder portions, while enabling both patterns to be properly connected continuously with each other.

In addition, the possibility of disconnection between the second portions 63B and the third portions 64B is certainly reduced. Similarly to the chamfered portions 12a, the chamfered portions 12b may be curved surfaces.

Yet further, the chamfered portions 16b similar to the chamfered portions 16b are formed in corner portions, which form border portions between the end portions of the fitting-recess portions 16 on the open side, in other words, the bottom surfaces of the leg portions 13, and internal side surfaces of the internal wall portions 13b. Similarly to the chamfered portions 16a, forming the chamfered portions 16b ensures continuity in the second conductive patterns 61B between the second portions 63B formed by plating on the external side surfaces of the inner wall portions 13b and the third portions 64B formed by plating on the internal side surfaces of the inner wall portions 13b. In addition, the possibility of disconnection between the second portions 63B and the third portions 64B is reduced. Further, similarly to the chamfered portions 12b, the chamfered portions 16b may be curved surfaces.

Although omitted in the example shown in the drawings, it is desirable that chamfered portions similar to the chamfered portions 16b are formed in corner portions which form border portions between the bottom surfaces of the leg portions 13 and the external side surfaces of the internal wall portions 13b. Accordingly, connection between the second portions 63B and the third portions 64B is ensured even further, and the possibility of disconnection between the second portions 63B and the third portions 64B is further reduced.

As shown in FIGS. 5, 7A, 7B, 8A and 8B, recessed surface portions 18, and guard projecting portions 17 serving as projecting portions to define both ends of the first conductive patterns 61A in the direction of array thereof in the recessed portions 18, are formed on the external side surfaces of the external wall portions 13a. The second portions 63A of the first conductive patterns 61A are formed on the recessed surface portions 18. Similarly, recessed surface portions 21, and guard projecting portions 22 serving as projecting portions to define both ends of the second conductive patterns 61B in the direction of array thereof in the recessed surface portions, are formed on the external side surfaces of the inner wall portions 13b. The second portions 63B of the second conductive patterns 61B are formed on the recessed surface portions 21.

As described above, since the guard projecting portions 17 and 22 projecting more outward than the recessed surface portions 18 and 21 are provided at both ends of the recessed portions 18 and 21, respectively, the second portions 63A of the first conductive patterns 61A and the second portions 63B of the second conductive patterns 61B do not slidably contact the fitting wall portions 123 even if the external wall portions 13a and the internal wall portions 13b enter the fitting groove portions 124 on both sides of the respective center wall portions 122 when the leg portions 13 on both sides of the connector 1 are fitted to the counterpart connectors 101. Therefore, even if the leg portions 13 are fitted to and withdrawn from the counterpart connectors 101 repeatedly, the second portions 63A and 63B are not damaged by slide contact with the fitting wall portions 123.

As described so far, in the present embodiment, the connector 1 is provided with the body portion 11 which is integrally formed of an insulating material and includes the plurality of leg portions 13 to be fitted to the counterpart connectors 101, respectively, and the conductive patterns 61 in three-dimensions, which are formed on the surfaces of the body portion 11, and the latter conductive patterns 61 always come into contact with the counterpart terminals 161 of the counterpart connectors 101, thus establishing mutual connection among the plurality of the counterpart connectors 101. To be more specific, the body portion 11 is provided with the plate-like bridging portion 12, and the leg portions 13 are connected to both ends of the bridging portion 12 in the direction in which the conductive patterns 61 extend, and extend in the direction perpendicular to the bridging portion 12.

Further, in the present embodiment, forming dies used for forming the body portion 11 have a shape to be opened in the upward and downward directions in FIGS. 8A and 8B, and form the leg portions 13 without forming any recessed shapes in the left and right directions in FIGS. 8A and 8B (i.e., the direction orthogonal to the opening direction of the die). In other words, the body portion 11 is formed without providing generally so-called undercuts in the injection molding, in the areas to form conductive patterns on the surfaces for the fitting-recess portions 16, the recessed surfaces 18 and 21, the guard projecting portions 17 and 22, and the like. Therefore, laser beam radiation can readily definitely reach the surfaces of the areas where the conductive patterns of the connector 1 are to be formed.

This means that, by having appropriate depths of the fitting-recess portions 16 and appropriate angles of the chamfered portions 12a, 12b, 16a and 16b, the first conductive patterns 61A and the second conductive patterns 61B can be formed only with radiation from three directions indicated by the arrows D, E, and F in FIG. 8B, and the body portion 11 can be produced with a small number of steps.

Further, in the bridging portion 12, it is preferred that the areas on the surface and rear surface of the bridging portion 12 where conductive patterns 61 are to be formed are flattened without any recesses or projections. This is because laser beam radiation in the direction of the arrow F may need to be divided into two directions depicted by the arrows F1 and F2 in FIG. 8B if, for example, a recessed portion is formed on the surface of the bridging portion 12. In that case, however, radiation of the beam of laser needs to be applied from only four directions, and the body portion 11 can be still produced with a small number of steps.

Furthermore, when the first conductive patterns 61A and the second conductive patterns 61B are formed in the body portion 11, it is common to apply radiation of the beam of laser from a constant definite direction and to change the direction of the body portion 11.

At that time, there is usually employed a method in which plural body portions 11 are lined up in a direction (direction of arrow M) orthogonal to the direction of laser beam radiation (direction of arrow L), and a source of the laser beam radiation is moved to the direction of the arrayed body portions 11 (direction of arrow M), as shown in FIGS. 9A and 9B. In this case, lining up the body portions 11 in a standing state against the direction of the laser beam radiation as much as possible, more numbers of body portions 11 can be lined up on a mounting surface thereof per a given unit area, and efficiency of the process is increased.

Compared with the case where no chamfered portions are formed, with the chamfered portions 16a and 16b formed, it becomes possible to transfer the body portions 11 in the standing state when forming the conductive patterns with a given depth in the fitting-recess portions 16. FIGS. 9A and 9B show a state where the body portions 11 are standing at 45 degrees against the direction of arrow M.

Further, assuming that the tilt angle of the body portions 11 in the transferring state is constant, it becomes possible to form the conductive patterns in even deeper areas of the fitting-recess portions 16 by forming the chamfered portions 16a and 16b, and the effective fitting length with the counterpart connectors can be extended.

Accordingly, an operation for fitting the body portion 11 to the counterpart connectors can be performed easily. In addition, desired conductive patterns 61 can be obtained, and short-circuits between terminals due to contact between the neighboring conductive patterns 61 do not occur. Moreover, the structure is simplified, and the number of components is reduced. Also, manufacturing is easy, and costs can be curtailed.

The conductive patterns 61 are provided with the first conductive patterns 61A which include the first portion 62A formed on the surface of the bridging portion 12 and the second portions 63A formed on the surfaces of the leg portions 13 and connected to the first portion 62A, and the second conductive patterns 61B which include the first portion 62B formed on the rear or inner surface of the bridging portion 12, and the second portions 63B formed on the rear surfaces of the leg portions 13 and connected to the first portion 62B. Since the conductive patterns 61 are formed on both surfaces of the body portion 11 as described above, a number of conductive patterns 61 can be wired at a high density, and counterpart connectors 101 having a large number of electrodes can be connected to each other.

Furthermore, the body portion 11 is provided with the chamfered portions 12a formed in the border portions between the surface of the bridging portion 12 and the surfaces of the leg portions 13, and the chamfered portions 12b formed in the border portions between the rear surface of the bridging portion 12 and the rear surfaces of the leg portions 13. Therefore, continuity is ensured between the first portion 62A formed on the surface of the bridging portion 12 and the second portions 63A formed on the surfaces of the leg portions 13, and continuity is ensured between the first portion 62B formed on the rear surface of the bridging portion 12 and the second portions 63B formed on the rear surfaces of the leg portions 13.

Yet further, the surfaces of the leg portions 13 include the recessed surface portions 18 on which the second portions 63A of the first conductive patterns 61A are formed, and the guard projecting portions 17 projecting further than the recessed surface portions 18, and the rear surfaces of the leg portions 13 include the recessed surface portions 21 on which the second portions 63B of the second conductive patterns 61B are formed, and the guard projecting portions 22 projecting further than the recessed surface portions 21. Hence, when the leg portions 13 are fitted to the counterpart connectors 101, the second portions 63A of the first conductive patterns 61A and the second portions 63B of the second conductive patterns 61B do not slidably contact the members of the counterpart connectors 101.

Yet further, the insulating material for the body portion 11 is made of a composite material in which organic metal is mixed in base polymer, and the conductive patterns 61 are formed of metal plating films deposited to the patterns formed by radiating a beam of laser onto the surfaces of the body portion 11. Therefore, the complex conductive patterns 61 in three-dimension, which are arrayed with a fine pitch can be formed on the surfaces of the intricately-shaped body portion 11. Even if the body portion 11 receives an external force and is deformed, short-circuits between terminals do not occur as the neighboring conductive patterns 61 do not come into contact with one another.

Next, a second embodiment of the present invention will be described. The portions having the same structures as the first embodiment are designated by the same reference numerals, and that way the descriptions thereof are omitted. Also, descriptions of the same operations and effects as the first embodiment will be omitted as well for the simplicity sake.

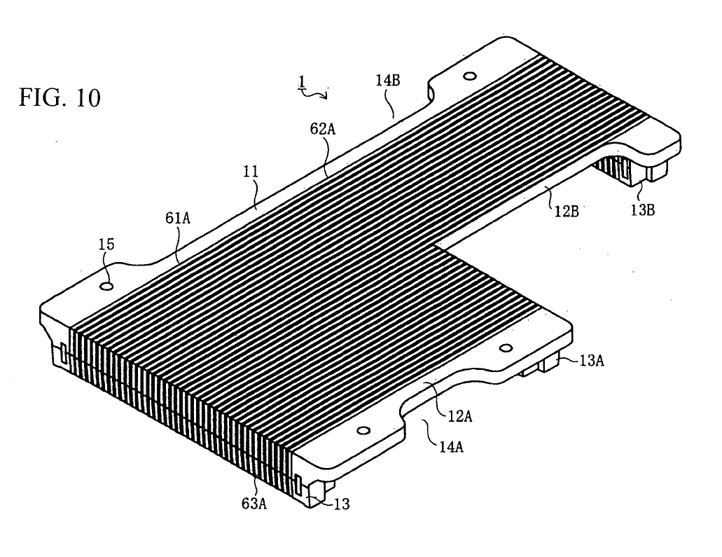

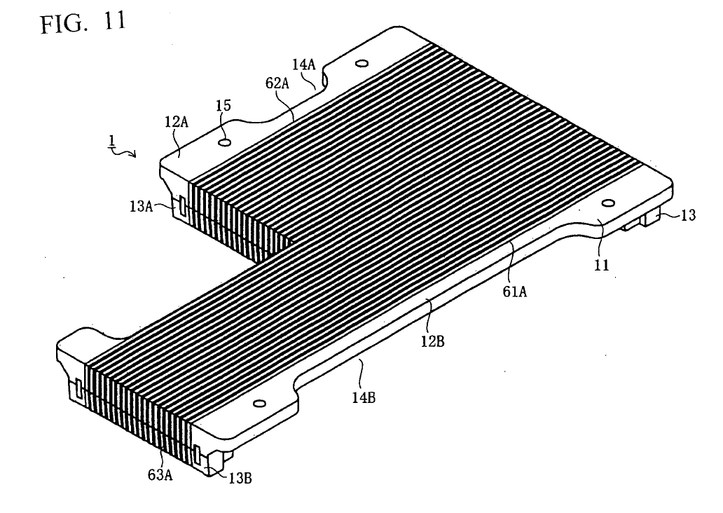

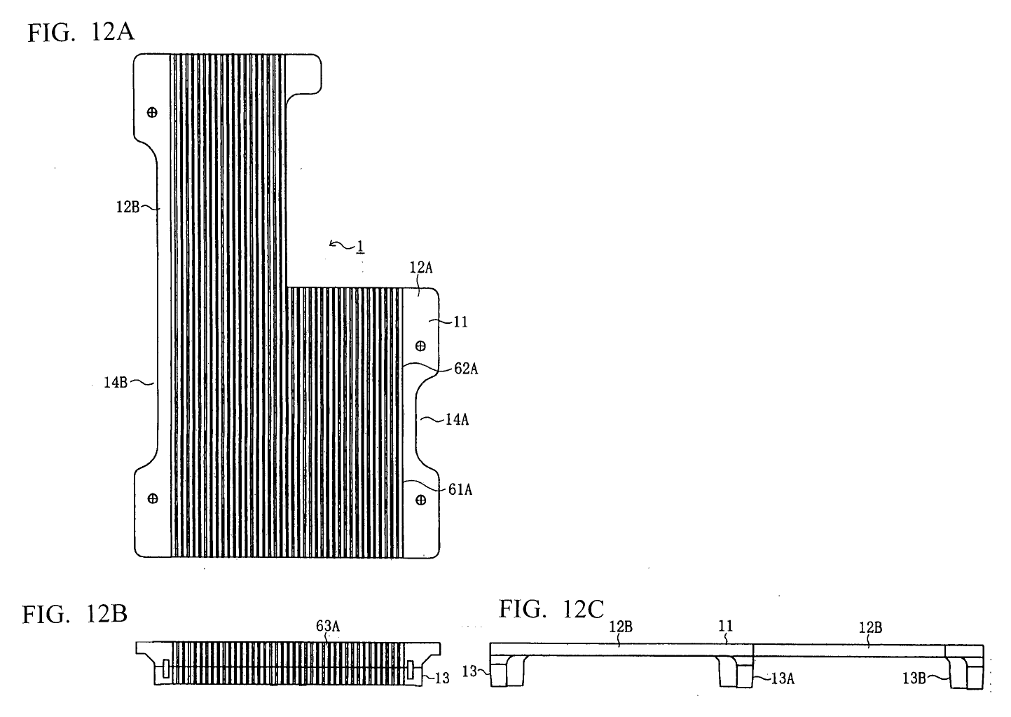

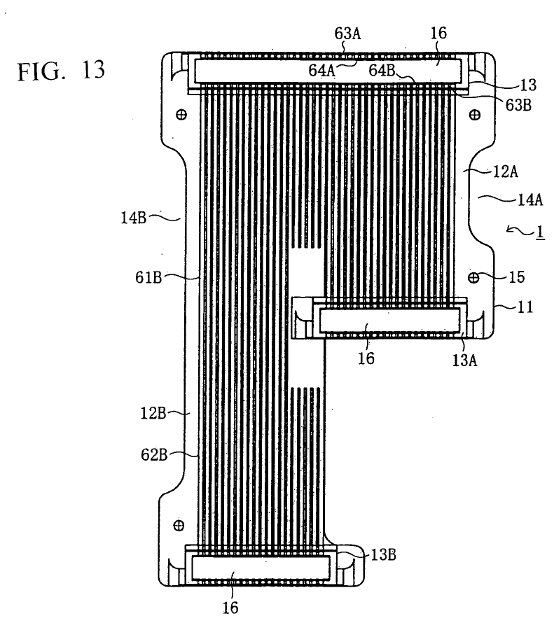

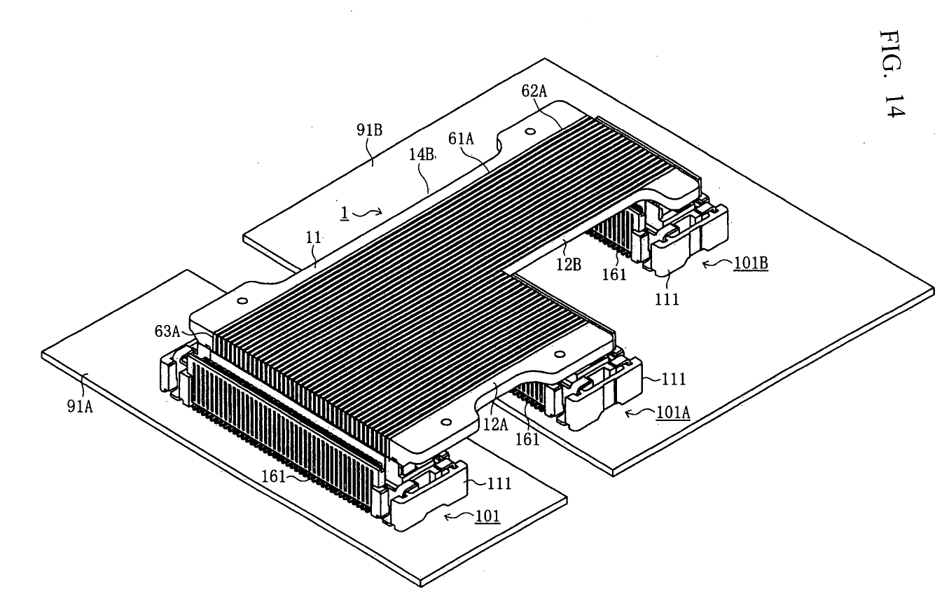

FIG. 10 is a first perspective view of a relay connector according to a second embodiment of the present invention, FIG. 11 is a second perspective view of the relay connector according to the second embodiment of the present invention, FIGS. 12A to 12C are three-sided views of the relay connector according to the second embodiment of the present invention, in which FIG. 12A is a top plan view thereof, FIG. 12B is a front view thereof, and FIG. 12C is a side view thereof, FIG. 13 is a bottom view of the relay connector according to the second embodiment of the present invention, and FIG. 14 is a perspective view illustrating a state where the relay connector according to the second embodiment of the present invention is fitted to counterpart connectors.

In the connector 1 of the present embodiment, one of the leg portions 13 is divided into two portions, a first leg portion 13A and a second leg portion 13B, with respect to a direction of array of the conductive patterns 61, and are arranged to be offset so that the locations thereof differ from each other with respect to the longitudinal direction of the conductive patterns 61. Note that the other leg portion 13 is one piece and is not divided. In this case, the bridging portion 12 is divided into two in the array direction of the conductive patterns 61 corresponding to the division of the leg portion 13 into the first leg portion 13A and the second leg portion 13B, and includes a shorter portion 12A and a longer portion 12B which have different lengths.

One ends of the shorter portion 12A and the longer portions 12B are arranged to form the same straight line, and are located at the same positions with respect to the longitudinal direction of the conductive patterns 61, so that the leg portion 13 is integrally connected to one ends of both of the shorter portion 12A and the longer portion 12B. The other ends of the shorter portion 12A and the longer portion 12B are at different locations relative to the longitudinal direction of the conductive patterns 61, the first leg portion 13A is integrally connected to the other end of the shorter portion 12A, and the second leg portion 13B is integrally connected to the other end of the longer portion 12B. Therefore, the distance from the leg portion 13, which is connected to one ends of both shorter portion 12A and the longer portion 12B, to the second leg portion 13B is longer than the distance from the leg portion 13 to the first leg portion 13A. Also, the first portion 62A of the first conductive patterns 61A formed on the surface of the longer portion 12B and the first portion 62B of the second conductive patterns 61B formed on the rear surface of the longer portion 12B are longer than the first portion 62A of the first conductive patterns 61A formed on the surface of the shorter portion 12A and the first portion 62B of the second conductive patterns 61B formed on the rear surface of the shorter portion 12A.

Reference numeral 14A represents a shorter manipulating recessed portion formed in the shorter portion 12A, and reference numeral 14B represents a longer manipulating recessed portion formed in the longer portion 12B. In the example illustrated in the drawings, the shorter manipulating recessed portions 14A and the longer manipulating recessed portions 14B are structured to have different sizes to correspond to the shorter portion 12A and the longer portion 12B, but the sizes thereof may be the same.

In the present invention, the leg portion 13, the first leg portion 13A and the second leg portion 13B have different dimensions with respect to the direction of array of the conductive patterns 61 only, and the rest of dimensions and structures thereof are identical. Moreover, the leg portion 13, the first leg portion 13A and the second leg portion 13B have structures similar to the legs portions 13 of the first embodiment. Further, the structure of the portions where the leg portion 13, the first leg portion 13A and the second leg portion 13B are connected to the shorter portion 12A and the longer portion 12B is similar to the structure of the portions where the leg portions 13 are connected to the bridging portion 12 in the first embodiment.

As shown in FIG. 14, a counterpart connector 101 to be fitted to the leg portion 13 is mounted on a first substrate 91A, and a first counterpart connector 101A and a second counterpart connector 101B to be fitted to the first leg portion 13A and the second leg portion 13B are mounted on a second substrate 91B. In this case, since the first counterpart connector 101A and the second counterpart connector 101B are mounted at locations corresponding to the first leg portion 13A and the second leg portions 13B, respectively, the first counterpart connector 101A and the second counterpart connector 101B are offset so that the locations thereof differ from each other with respect to the longitudinal direction of the conductive patterns 61.

Further, in the present embodiment, the counterpart connector 101, the first counterpart connector 101A and the second counterpart connector 101B have different dimensions from each other with respect to the direction of array of the conductive patterns 61 only, and the rest of the dimensions and structures thereof are identical. In addition, the counterpart connector 101, the first counterpart connector 101A and the second counterpart connector 101B have structures similar to the counterpart connectors 101 of the first embodiment.

The rest of structures, the methods for manufacturing the conductive patterns 61 and the body portion 11, how to fit the connector 1 to the counterpart connectors 101, and so forth are similar to those of the first embodiment, and the descriptions thereof are thus omitted.

In the present embodiment, such an example was described in which the leg portion 13 and the bridging portion 12 are divided into two in the array direction of the conductive patterns 61, but the leg portion 13 and the bridging portion 12 can be divided into three or more in the array direction of the conductive patterns 61.

Also, in the present invention, the dimensions of the divided portions are approximately the same with respect to the array direction of the conductive patterns 61, but the ratio of the dimensions of the divided portions with respect to the direction of array of the conductive patterns 61 may be set arbitrarily and optionally.

Moreover, in the present invention, the example was described where only one of the leg portions 13 is divided and the other leg portion 13 is not divided and is a single piece, but the other leg portion 13 may be divided as well.

As described above, in the present embodiment, at least one of the leg portions 13 is divided into a plurality of portions with respect to the array direction of the conductive patterns 61, and the plurality of divided portions are offset so that the locations thereof are different from each other with respect to the longitudinal direction of the conductive patterns 61. Therefore, the number and locations of the leg portions 13 can be set arbitrarily. Hence, even if the locations of the counterpart connectors 101 to be mounted on the first substrate 91A and the second substrate 91B are decided arbitrarily, the leg portions 13 can be arranged at locations corresponding to the locations of the counterpart connectors 101, and counterpart connectors 101 can be connected to each other by the single connector 1.

The present invention is not limited to the above-described embodiments, and may be changed in various ways based on the gist of the present invention, and these changes are not eliminated from the scope of the present invention.

1. A relay connector comprising:
a body portion provided with a plurality of fitting portions to be fitted to counterpart connectors, respectively, and integrally formed of an insulating material; and
conductive patterns in three-dimension, which are formed on surfaces of the body portion;
the conductive patterns being capable of coming into contact with counterpart terminals of the counterpart connectors, thereby connecting the plurality of counterpart connectors to one another.

2. The relay connector according to claim 1, wherein the body portion is provided with a plate-like bridging portion and the fitting portions are connected to the bridging portion at both ends of the bridging portion spaced apart in a direction in which the conductive patterns extend, and the fitting portions extending, respectively, in a direction perpendicular to the bridging portion.

3. The relay connector according to claim 2, wherein the conductive patterns have:
first conductive patterns which include a first portion formed on a surface of the bridging portion, and second portions formed on surfaces of the fitting portions and connected to the first portion; and
second conductive patterns which include a first portion formed on a rear surface of the bridging portion, and second portions formed on rear surfaces of the fitting portions and connected to the first portion.

4. The relay connector according to claim 3, wherein the body portion has:
chamfered portions formed in border portions between the surface of the bridging portion and the surfaces of the fitting portions; and
chamfered portions formed in border portions between the rear surface of the bridging portion and the rear surfaces of the fitting portions.

5. The relay connector according to claim 4, wherein:
at least one of the fitting portions is divided into a plurality of portions with respect to a direction of array of the conductive patterns; and
the plurality of portions are arranged to be offset such that locations thereof differ from one another with respect to a longitudinal direction of the conductive patterns.

6. The relay connector according to claim 5, wherein:
the insulating material comprises a composite material obtained by mixing organic metal with base polymer; and
the conductive patterns are formed of a metal plating film deposited on patterns formed by radiating a beam of laser onto the surfaces of the body portion.

7. The relay connector according to claim 1, wherein:
at least one of the fitting portions is divided into a plurality of portions with respect to a direction of array of the conductive patterns; and
the plurality of portions are arranged to be offset such that locations thereof differ from one another with respect to a longitudinal direction of the conductive patterns.

8. The relay connector according to claim 7, wherein:
the insulating material comprises a composite material obtained by mixing organic metal with base polymer; and
the conductive patterns are formed of a metal plating film deposited on patterns formed by radiating a beam of laser onto the surfaces of the body portion.

9. The relay connector according to claim 1, wherein:
the insulating material comprises a composite material obtained by mixing organic metal with base polymer; and
the conductive patterns are formed of a metal plating film deposited on patterns formed by radiating a beam of laser onto the surfaces of the body portion.

10. The relay connector according to claim 2, wherein:
at least one of the fitting portions is divided into a plurality of portions with respect to a direction of array of the conductive patterns; and
the plurality of portions are arranged to be offset such that locations thereof differ from one another with respect to a longitudinal direction of the conductive patterns.

11. The relay connector according to claim 11, wherein:
the insulating material comprises a composite material obtained by mixing organic metal with base polymer; and
the conductive patterns are formed of a metal plating film deposited on patterns formed by radiating a beam of laser onto the surfaces of the body portion.

12. The relay connector according to claim 2, wherein:
the insulating material comprises a composite material obtained by mixing organic metal with base polymer; and
the conductive patterns are formed of a metal plating film deposited on patterns formed by radiating a beam of laser onto the surfaces of the body portion.

13. The relay connector according to claim 3, wherein:
at least one of the fitting portions is divided into a plurality of portions with respect to a direction of array of the conductive patterns; and
the plurality of portions are arranged to be offset such that locations thereof differ from one another with respect to a longitudinal direction of the conductive patterns.

14. The relay connector according to claim 13, wherein:
the insulating material comprises a composite material obtained by mixing organic metal with base polymer; and
the conductive patterns are formed of a metal plating film deposited on patterns formed by radiating a beam of laser onto the surfaces of the body portion.

15. The relay connector according to claim 3, wherein:
the insulating material comprises a composite material obtained by mixing organic metal with base polymer; and
the conductive patterns are formed of a metal plating film deposited on patterns formed by radiating a beam of laser onto the surfaces of the body portion.

16. The relay connector according to claim 4, wherein:
the surfaces of the fitting portions include recessed surface portions on which the second portions of the first conductive patterns are formed, and projecting portions projecting further than the recessed surface portions; and
the rear surfaces of the fitting portions include recessed surface portions on which the second portions of the second conductive patterns are formed, and projecting portions projecting further than the recessed surface portions.

17. The relay connector according to claim 16, wherein:
at least one of the fitting portions is divided into a plurality of portions with respect to a direction of array of the conductive patterns; and
the plurality of portions are arranged to be offset such that locations thereof differ from one another with respect to a longitudinal direction of the conductive patterns.

18. The relay connector according to claim 18, wherein:
the insulating material comprises a composite material obtained by mixing organic metal with base polymer; and
the conductive patterns are formed of a metal plating film deposited on patterns formed by radiating a beam of laser onto the surfaces of the body portion.

19. The relay connector according to claim 4, wherein:
the insulating material comprises a composite material obtained by mixing organic metal with base polymer; and
the conductive patterns are formed of a metal plating film deposited on patterns formed by radiating a beam of laser onto the surfaces of the body portion.

20. The relay connector according to claim 16, wherein:
the insulating material comprises a composite material obtained by mixing organic metal with base polymer; and
the conductive patterns are formed of a metal plating film deposited on patterns formed by radiating a beam of laser onto the surfaces of the body portion.
